(19) United States
(12) Patent Application Publication
(10) Pub. No.: US 2010/0207696 A1
(43) Pub. Date: Aug. 19, 2010

(54) PIEZOELECTRIC VIBRATOR, METHOD FOR MANUFACTURING PIEZOELECTRIC VIBRATOR, AND OSCILLATOR

(76) Inventor: Kiyotaka Sayama, Chiba-shi (JP)

Correspondence Address: Brinks Hofer Gilson & Lione/Seiko Instruments Inc., P.O. Box 10395, Chicago, IL, 60611, US

(21) Appl. No.: 12/701,027

(22) Filed: Feb. 5, 2010

(30) Foreign Application Priority Data
Feb. 13, 2009 (JP) JP2009-031705

(51) Int. Cl. H03B 5/36; H01L 41/053; H01L 41/22

(52) U.S. Cl. 331/158; 310/348; 29/25.35

(57) ABSTRACT

There is provided a piezoelectric vibrator that can hold the crystal plate parallel to the base substrate regardless of the shape of the crystal plate. A method for manufacturing the piezoelectric vibrator, and an oscillator are also provided. The piezoelectric vibrator includes a base substrate; a lid substrate; a piezoelectric vibrating piece including a crystal plate having on its outer surface excitation electrodes and mount electrodes; through electrodes provided in through holes formed through the base substrate; inner electrodes formed on the upper surface of the base substrate; and metal bumps formed at predetermined positions of the inner electrodes. The piezoelectric vibrating piece is tapered towards the ends along the longitudinal direction, and mounted on the metal bumps in a cantilever fashion. The metal bumps are provided in a plurality along the longitudinal direction of the piezoelectric vibrating piece, and have heights that become higher towards a position corresponding to an end of the piezoelectric vibrating piece along the longitudinal direction.

### RELATED APPLICATIONS

This application claims priority under 35 U.S.C. §119 to Japanese Patent Application No. 2009-031705 filed on Feb. 13, 2009, the entire content of which is hereby incorporated by reference.

### FIELD OF THE INVENTION

The present invention relates to a piezoelectric vibrator, a method for manufacturing a piezoelectric vibrator, and an oscillator.

### BACKGROUND ART

Piezoelectric vibrators that use crystals or other materials for applications such as a clock source, a timing source of control signals, and a reference signal source have been used in cellular phones and personal digital assistant units. The piezoelectric vibrators of this kind are available in a variety of forms. One known example is a thickness shear vibrator (AT vibrator) suitably used as the vibrator for control with MHz oscillating frequencies, and for communication devices, as described in, for example, Japanese Patent No. 3,911,838.

The AT vibrator generally includes a piezoelectric vibrating piece, and a base substrate and a lid substrate which together house the piezoelectric vibrating piece therein. As described in the foregoing Japanese patent, the piezoelectric vibrating piece is in the form of a plate having a constant thickness, and includes a crystal plate rectangular in shape in a planar view, and excitation electrodes, extraction electrodes, and mount electrodes formed on the both surfaces of the crystal plate. Specifically, the excitation electrodes are formed on the opposing surfaces at substantially the center of the crystal plate. The mount electrodes are formed at the end of the crystal plate by being electrically connected to the excitation electrodes via the extraction electrodes. The mount electrodes are formed on the both surfaces of the crystal plate: one being connected to one of the excitation electrodes, and the other connected to the other excitation electrode. The mount electrode formed on one surface of the crystal plate bends around the side of the crystal plate to be electrically connected to the mount electrode formed on the other surface.

The mount electrodes of the piezoelectric vibrating piece are so positioned as to be mounted on the bumps formed on the base substrate. The bumps are electrically connected to inner electrodes, which in turn are electrically connected to external electrodes via through electrodes. With this configuration, current can be applied to the excitation electrodes of the piezoelectric vibrating piece from the external electrodes.

### SUMMARY OF THE INVENTION

The configuration described above presents no problem as long as the crystal plate used for the piezoelectric vibrating piece is a plate having a constant thickness.

However, in a recent variation, a beveled crystal plate 101 or a convex crystal plate 102 of a non-uniform thickness has been used as a crystal plate 101 or 102 for the piezoelectric vibrating piece, as illustrated in FIGS. 13 and 14. When the beveled or convex crystal plate 101 or 102 is bump connected to the base substrate, there are cases where the crystal plate cannot be held parallel to a base substrate 103 and tilts, as illustrated in FIG. 15. In the event where the crystal plate tilts over a wide angle and the crystal plate 101 contacts the base substrate 103, the electrical characteristics of the piezoelectric vibrator are adversely affected, and the intended electrical characteristics may not be obtained.

The present invention has been made under these circumstances, and an object of the present invention is to provide a piezoelectric vibrator that can hold the crystal plate parallel to the base substrate regardless of the shape of the crystal plate. It is another object of the present invention to provide a method for manufacturing the piezoelectric vibrator, and an oscillator.

In order to solve the foregoing problem, the present invention provides the following.

A piezoelectric vibrator of the present invention includes: a base substrate; a lid substrate bonded to the base substrate in an opposing configuration; a piezoelectric vibrating piece housed in a cavity formed between the base substrate and the lid substrate, the piezoelectric vibrating piece being bonded to the upper surface of the base substrate, and including a crystal plate having on its outer surface excitation electrodes and mount electrodes electrically connected to the excitation electrodes; through electrodes provided in through holes formed through the base substrate; inner electrodes formed on the upper surface of the base substrate to provide electrical interconnections between the piezoelectric vibrating piece and the through electrodes; and metal bumps formed at predetermined positions of the inner electrodes to provide electrical interconnections between the inner electrodes and the mount electrodes. The piezoelectric vibrating piece is tapered towards the ends along the longitudinal direction, and mounted on the metal bumps in a cantilever fashion. The metal bumps are provided in a plurality along the longitudinal direction of the piezoelectric vibrating piece, and having heights that become higher towards a position corresponding to an end of the piezoelectric vibrating piece along the longitudinal direction.

In a piezoelectric vibrator according to the present invention, the electrical interconnections between the metal bumps and the mount electrodes of the piezoelectric vibrating piece are made by the metal bumps of heights corresponding to the distance created between the surface of the base substrate (the surface of the inner electrodes) and the surface of the crystal plate (the surface of the mount electrodes) when the crystal plate and the base substrate are held parallel to each other. Thus, even though the crystal plate is tapered towards the ends, bump bonding can be made with the axial direction of the piezoelectric vibrating piece held parallel to the base substrate. That is, the piezoelectric vibrating piece can be held the crystal plate parallel to the base substrate regardless of the shape of the crystal plate. Further, because the piezoelectric vibrating piece is supported by a plurality of metal bumps, the piezoelectric vibrating piece can be held parallel to the base substrate more reliably.

In one aspect of a piezoelectric vibrator of the present invention, the piezoelectric vibrating piece is an AT-cut vibrating piece.

According to this aspect of a piezoelectric vibrator of the present invention, a piezoelectric vibrator can be provided that has an AT-cut vibrating piece having easily adjustable oscillating frequency bands, and excellent frequency stability in a wide temperature range.

In another aspect of a piezoelectric vibrator of the present invention, the metal bumps are gold bumps.

According to this aspect of a piezoelectric vibrator of the present invention, the bump bonding of the piezoelectric vibrating piece to the gold bumps can be made by melting only the tip portion of the bumps using ultrasonic waves. Thus, even when the piezoelectric vibrating piece is tapered towards the ends along the longitudinal direction, bump bonding is ensured that conforms to the shape at the end of the piezoelectric vibrating piece, with the piezoelectric vibrating piece and the base substrate held parallel to each other.

In another aspect of a piezoelectric vibrator of the present invention, the crystal plate has a beveled or convex shape.

According to this aspect of a piezoelectric vibrator of the present invention, the electrical characteristics of the piezoelectric vibrator, such as frequency characteristics and impedance characteristics can be stabilized.

A manufacturing method of a piezoelectric vibrator of the present invention is a method for manufacturing a piezoelectric vibrator which includes: a base substrate; a lid substrate bonded to the base substrate in an opposing configuration; a piezoelectric vibrating piece housed in a cavity formed between the base substrate and the lid substrate, the piezoelectric vibrating piece being bonded to the upper surface of the base substrate, and including a crystal plate having on its outer surface excitation electrodes and mount electrodes electrically connected to the excitation electrodes; through electrodes provided in through holes formed through the base substrate; inner electrodes formed on the upper surface of the base substrate to provide electrical interconnections between the piezoelectric vibrating piece and the through electrodes; and metal bumps formed at predetermined positions of the inner electrodes to provide electrical interconnections between the inner electrodes and the mount electrodes, the piezoelectric vibrating piece being tapered towards the ends along the longitudinal direction, and mounted on the metal bumps in a cantilever fashion.

The method includes the steps of:
forming the inner electrodes on the upper surface of the base substrate;
forming the metal bumps at predetermined positions of the inner electrodes along the longitudinal direction of the piezoelectric vibrating piece; and
bonding the mount electrodes of the piezoelectric vibrating piece to the metal bumps,
the metal bumps being formed so that the heights of the metal bumps become higher towards a position corresponding to an end of the piezoelectric vibrating piece along the longitudinal direction.

According to this aspect of a manufacturing method of a piezoelectric vibrator of the present invention, the electrical interconnections between the metal bumps and the mount electrodes of the piezoelectric vibrating piece are made by the metal bumps of heights corresponding to the distance created between the surface of the base substrate (the surface of the inner electrodes) and the surface of the crystal plate (the surface of the mount electrodes) when the crystal plate and the base substrate are held parallel to each other. Thus, even though the crystal plate is tapered towards the ends, bump bonding can be made with the axial direction of the piezoelectric vibrating piece held parallel to the base substrate. That is, the piezoelectric vibrating piece can be held the crystal plate parallel to the base substrate regardless of the shape of the crystal plate. Further, because the piezoelectric vibrating piece is supported by a plurality of metal bumps, the piezoelectric vibrating piece can be held parallel to the base substrate more reliably.

In an oscillator of the present invention, any of the piezoelectric vibrators described above is electrically connected as a resonator to an integrated circuit.

According to this aspect of an oscillator of the present invention, because the piezoelectric vibrator having stable electrical characteristics such as frequency characteristics and impedance characteristics is used, a high-quality oscillator with stable electrical characteristics can be provided.

According to a piezoelectric vibrator of the present invention, the electrical interconnections between the metal bumps and the mount electrodes of the piezoelectric vibrating piece are made by the metal bumps of heights corresponding to the distance created between the surface of the base substrate (the surface of the inner electrodes) and the surface of the crystal plate (the surface of the mount electrodes) when the crystal plate and the base substrate are held parallel to each other. Thus, even when the crystal plate is tapered towards the ends, bump bonding can be made with the axial direction of the piezoelectric vibrating piece held parallel to the base substrate. That is, the piezoelectric vibrating piece can be held crystal plate parallel to the base substrate regardless of the shape of the crystal plate. Further, because the piezoelectric vibrating piece is supported by a plurality of metal bumps, the piezoelectric vibrating piece can be held parallel to the base substrate more reliably.

### BRIEF DESCRIPTION OF THE DRAWINGS

FIG. 1 is a view showing a schematic illustration of a structure of a piezoelectric vibrator of an embodiment of the present invention.

FIG. 2 is a cross sectional view taken along the line A-A of FIG. 1.

FIG. 3 is a horizontal sectional view of a piezoelectric vibrator of an embodiment of the present invention.

FIG. 4 is an exploded perspective view of a piezoelectric vibrator of an embodiment of the present invention.

FIG. 5 is an explanatory diagram illustrating a method of forming bumps in an embodiment of the present invention.

FIG. 6 is a flow chart representing a manufacturing method of a piezoelectric vibrator of an embodiment of the present invention.

FIG. 7 is an illustration of one of the manufacturing steps of forming a piezoelectric vibrator along the flow chart of FIG. 6, showing a state in which a plurality of depressions is formed in a lid substrate wafer formed into a lid substrate.

FIG. 8 is an illustration of one of the manufacturing steps of forming a piezoelectric vibrator along the flow chart of FIG. 6, showing a state in which a bonding film and inner electrodes are patterned on the upper surface of a base substrate wafer.

FIG. 9 is a partially enlarged perspective view of FIG. 8.

FIG. 10 is an exploded perspective view of one of the manufacturing steps of forming a piezoelectric vibrator along the flow chart of FIG. 6, showing a wafer unit formed by the anodic bonding of a base substrate wafer and a lid substrate wafer with the piezoelectric vibrating piece housed in the cavity.

FIG. 11 is a view showing a schematic illustration of a structure of an oscillator in which a piezoelectric vibrator of an embodiment of the present invention is installed.

FIG. 12 is an explanatory diagram illustrating another aspect of a method of forming bumps in an embodiment of the present invention.

FIG. 13 is a perspective view illustrating a beveled crystal plate.

FIG. 14 is a perspective view illustrating a convex crystal plate.

FIG. 15 is an explanatory diagram illustrating a state in which a beveled crystal is bump bonded using a conventional method.

### DETAILED DESCRIPTION OF THE PREFERRED EMBODIMENTS

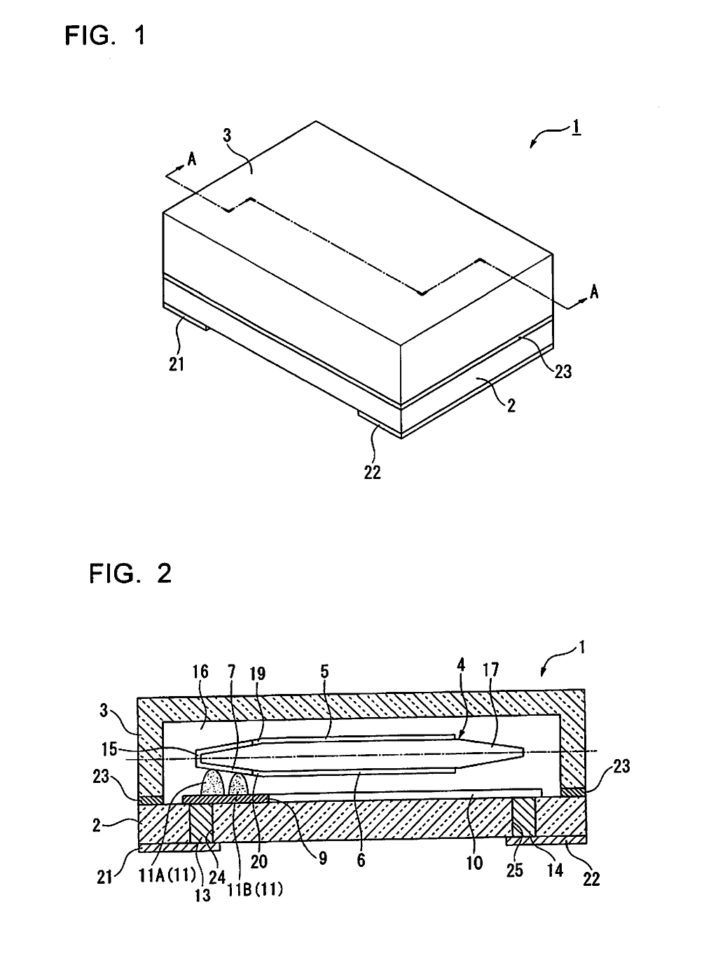

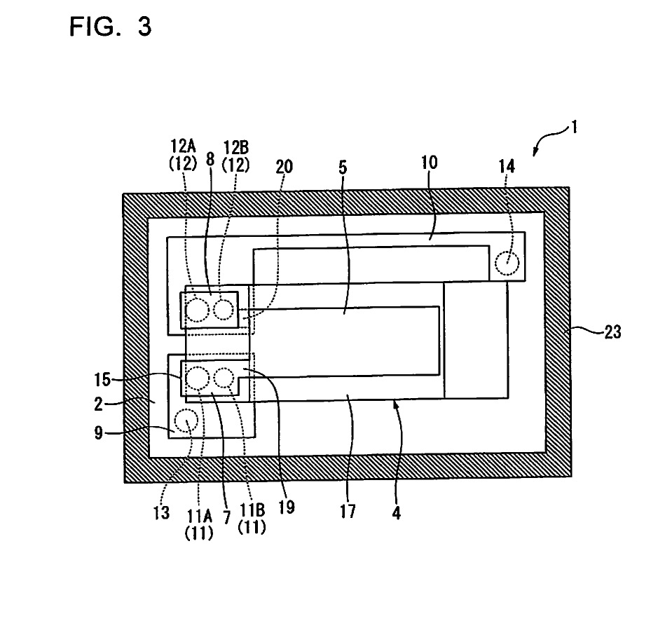

An embodiment of a piezoelectric vibrator according to the present invention is described below with reference to FIG. 1 to FIG. 10.

As illustrated in FIG. 1 to FIG. 4, a piezoelectric vibrator 1 is a surface-mounted piezoelectric vibrator including a base substrate 2 and a lid substrate 3 stacked together in two layers in the form of a box, and a piezoelectric vibrating piece 4 housed in a cavity 16 formed inside the vibrator.

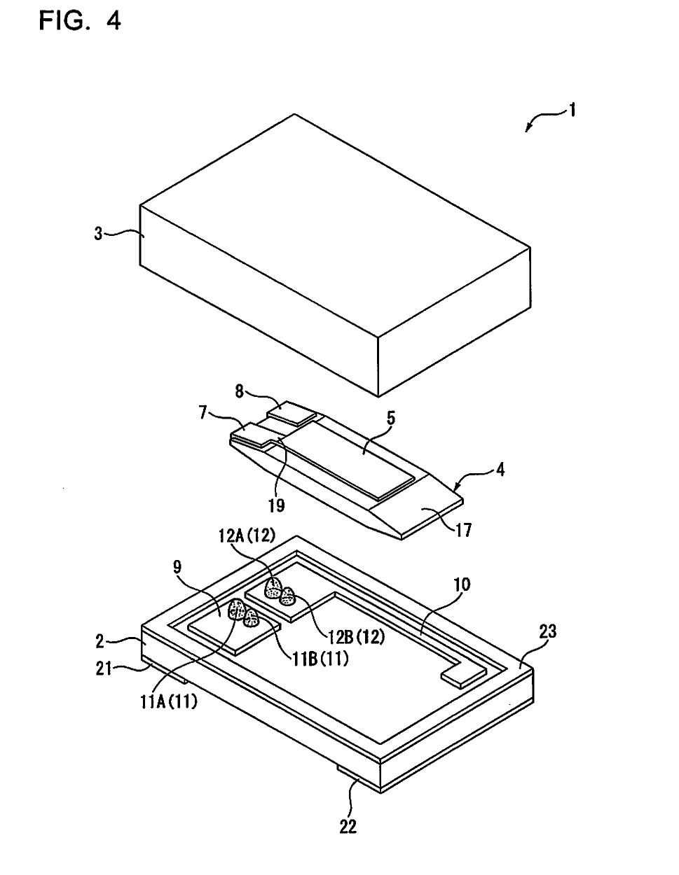

In FIG. 4, through electrodes 13 and 14, and through holes 24 and 25, described later, are not illustrated for ease of illustration.

The piezoelectric vibrating piece 4 is an AT-cut vibrating piece formed from a crystal of piezoelectric material, and vibrates in response to an applied predetermined voltage.

The piezoelectric vibrating piece 4 includes a crystal plate 17 substantially rectangular in shape in a planar view and having a beveled cross section, a pair of excitation electrodes 5 and 6 disposed on the opposing faces of the crystal plate 17, extraction electrodes 19 and 20 electrically connected to the excitation electrodes 5 and 6, and mount electrodes 7 and 8 electrically connected to the extraction electrodes 19 and 20. The mount electrode 7 is electrically connected to a side electrode 15 of the crystal plate 17 so as to be electrically connected to the mount electrode 7 formed on the side of the crystal plate 17 where the excitation electrode 6 is provided.

The excitation electrodes 5 and 6, the extraction electrodes 19 and 20, the mount electrodes 7 and 8, and the side electrode 15 are formed as conductive film coatings of, for example, chromium (Cr), nickel (Ni), gold (Au), aluminum (Al), or titanium (Ti), or as laminated films of such conductive films.

The piezoelectric vibrating piece 4 structured as above is bump bonded on an upper surface of the base substrate 2 using bumps 11 and 12 made of, for example, gold. Specifically, the piezoelectric vibrating piece 4 is bump bonded with the mount electrodes 7 and 8 respectively in contact with the bumps 11 and 12 respectively formed on inner electrodes 9 and 10 (described later) patterned on the upper surface of the base substrate 2. In this way, the piezoelectric vibrating piece 4 is supported by being suspended above the base substrate 2 with the distance corresponding to the thickness of the bumps 11 and 12, with the mount electrodes 7 and 8 and the inner electrodes 9 and 10 being electrically connected to each other, respectively.

A method of bonding the piezoelectric vibrating piece 4 (mount electrode 7) and the bumps 11 is described below. Note that the method of bonding the mount electrode 8 and the bumps 12 is essentially the same as the bonding method for the mount electrode 7 and the bumps 11, and therefore will not be described.

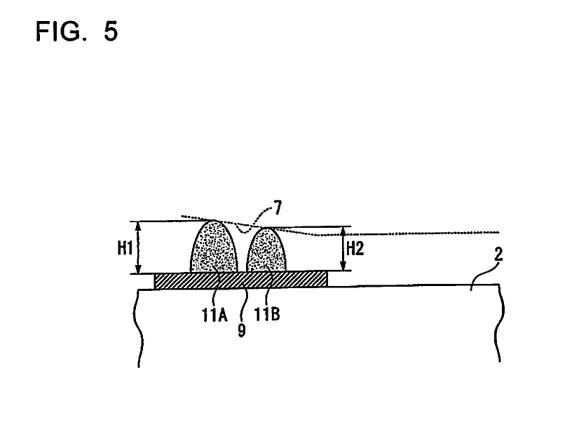

The crystal plate 17 of the present embodiment is shaped to have a beveled cross section. Specifically, the crystal plate 17 is tapered towards the ends along the longitudinal direction, and as such the distance between the surface of the base substrate 2 and the tapered surface of the crystal plate 17 will not be constant even when the axial direction (the direction parallel to the surfaces the excitation electrodes 5 and 6 are formed) of the crystal plate 17 is disposed parallel to the surface of the base substrate 2. As a countermeasure, in the present embodiment, two bumps 11 of different heights are formed for the inner electrode 9 along the longitudinal direction of the crystal plate 17. Specifically, as illustrated in FIG. 5, two bumps 11A and 11B of different heights are formed along the longitudinal direction of the crystal plate 17. The bump 11A has height H1 substantially the same as the gap between the surface of the inner electrode 9 (base substrate 2) and the surface of the crystal plate 17 (mount electrode 7) to be bump bonded to the bump 11A. The bump 11B has height H2 substantially the same as the gap between the surface of the inner electrode 9 (base substrate 2) and the surface of the crystal plate 17 (mount electrode 7) to be bump bonded to the bump 11B.

With this construction, the bump bonding of the mount electrode 7 of the crystal plate 17 to the bumps 11A and 11B ensures that the crystal plate 17 is supported with its axial direction held parallel to the surface of the base substrate 2.

The lid substrate 3 is a transparent insulating substrate made of a glass material, for example, soda-lime glass. On the side of the surface bonded to the base substrate 2 is provided a rectangular depression (cavity) 16 where the piezoelectric vibrating piece 4 is housed. The depression 16 is formed to provide a cavity when the base substrate 2 and the lid substrate 3 are mated, thus providing the cavity 16 for housing the piezoelectric vibrating piece 4. The lid substrate 3 is anodically bonded to the base substrate 2 with the depression 16 facing the base substrate 2.

As with the lid substrate 3, the base substrate 2 is a transparent insulating substrate made of a glass material, for example, soda-lime glass. The base substrate 2 is substantially planar in shape, and sized to be mated with the lid substrate 3.

The base substrate 2 includes a pair of through holes 24 and 25 formed through the base substrate 2. One end of the through holes 24 and 25 opens into the cavity 16. Specifically, the through hole 24 is provided on the side of the mount electrodes 7 and 8 of the piezoelectric vibrating piece 4 mounted in position, and the through hole 25 is provided on the opposite side from the mount electrodes 7 and 8 of the piezoelectric vibrating piece 4. Further, the through holes 24 and 25 are provided through the base substrate 2 substantially cylindrically, parallel to the thickness direction of the base substrate 2. The through holes 24 and 25 may be tapered to gradually increase or decrease their diameters towards the lower surface of the base substrate 2, for example.

In the through holes 24 and 25, a pair of through electrodes 13 and 14 is provided, plugging the through holes 24 and 25. The through electrodes 13 and 14 are provided to close the through holes 24 and 25 and thereby maintain the cavity 16 air-tight, and to provide conduction between external electrodes 21 and 22 (described later) and the inner electrodes 9 and 10, respectively. The gaps between the through holes 24 and 25 and the through electrodes 13 and 14 are completely closed with a glass fit material (not shown) having substantially the same coefficient of thermal expansion as the glass material used for the base substrate 2.

The upper surface side (the side bonded to the lid substrate 3) of the base substrate 2 are patterned with a bonding film 23 for anodic bonding, and the inner electrodes 9 and 10, using a conductive material (for example, such as aluminum and silicon). The bonding film 23 is formed along the periphery of the base substrate 2, surrounding the depression 16 formed in the lid substrate 3.

The inner electrodes 9 and 10 are patterned to provide electrical interconnections between the through electrode 13 and the mount electrode 7 of the piezoelectric vibrating piece 4, and between the other through electrode 14 and the other mount electrode 8 of the piezoelectric vibrating piece 4. Specifically, the inner electrode 9 is formed directly above the through electrode 13 on the side of the mount electrodes 7 and 8 of the piezoelectric vibrating piece 4. The other inner electrode, the inner electrode 10, is formed directly above the through electrode 14 by being routed along the piezoelectric vibrating piece 4 from the position adjacent to the inner electrode 9 to the side opposite from the through electrode 13 appearing on the base substrate 2.

The bumps 11 and 12 are formed on the inner electrodes 9 and 10, and the piezoelectric vibrating piece 4 is mounted using the bumps 11 and 12. This provides conduction between the mount electrode 7 of the piezoelectric vibrating piece 4 and the through electrode 13 via the inner electrode 9, and between the mount electrode 8 and the through electrode 14 via the inner electrode 10.

On the lower surface of the base substrate 2 are provided external electrodes 21 and 22 electrically connected to the through electrodes 13 and 14, respectively. Specifically, one of the external electrodes, the external electrode 21, is electrically connected to the first excitation electrode, 5, of the piezoelectric vibrating piece 4 via the through electrode 13 and the inner electrode 9. The other external electrode, the external electrode 22, is electrically connected to the second excitation electrode, 6, of the piezoelectric vibrating piece 4 via the through electrode 14 and the inner electrode 10.

The piezoelectric vibrator 1 structured as above is activated by applying a predetermined drive voltage to the external electrodes 21 and 22 formed on the base substrate 2. In response, current flows through the first and second excitation electrodes 5 and 6 of the piezoelectric vibrating piece 4, causing vibration at a predetermined frequency. The vibration can then be used as the timing source of control signals, or the reference signal source.

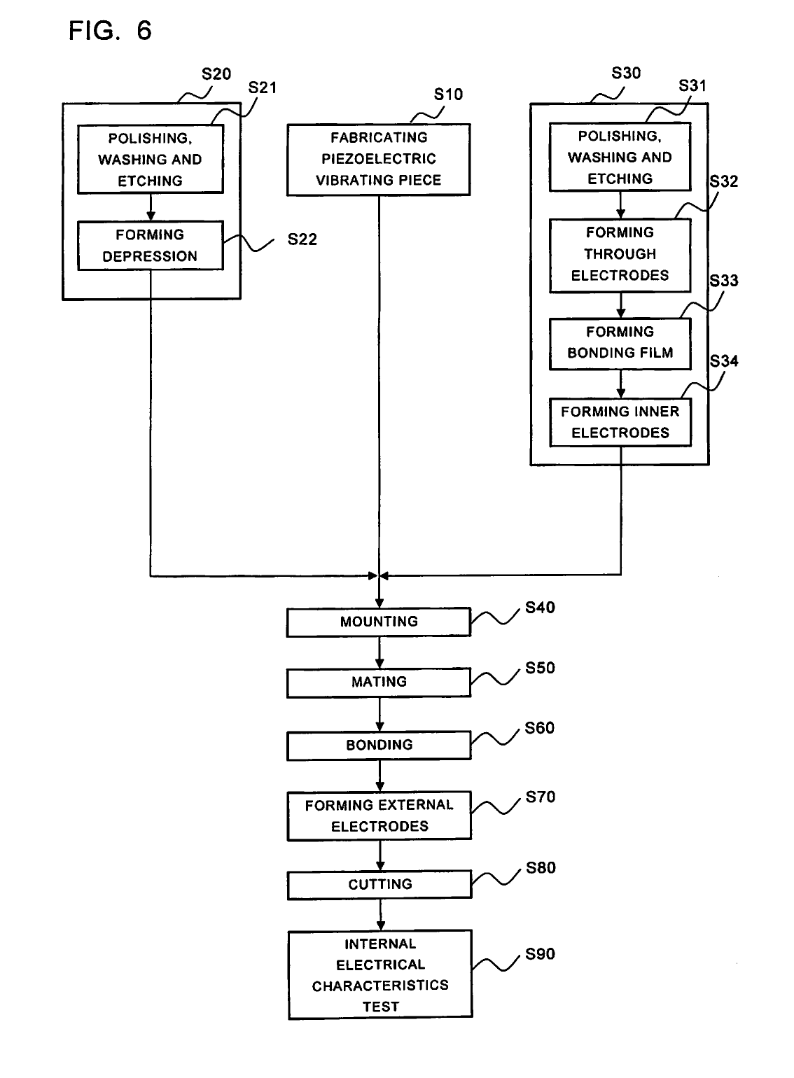

The following describes a method for manufacturing a plurality of piezoelectric vibrators 1 at once using a base substrate wafer 40 and a lid substrate wafer 50, with reference to the flow chart of FIG. 6.

First, the piezoelectric vibrating piece 4 illustrated in FIG. 2 to FIG. 4 is fabricated in a piezoelectric vibrating piece fabrication step (S10). Specifically, a crystal of a Lumbered quartz bar is sliced at a predetermined angle to provide a wafer of a constant thickness. The wafer is then coarsely processed by lapping, and shaped to provide a beveled cross section using a barrel machine or the like. After appropriately processing the wafer by treatment such as washing, a metal film is deposited and patterned on the wafer by a photolithography technique to form the excitation electrodes 5 and 6, the extraction electrodes 19 and 20, the mount electrodes 7 and 8, and the side electrode 15. This completes the fabrication of a plurality of piezoelectric vibrating pieces 4.

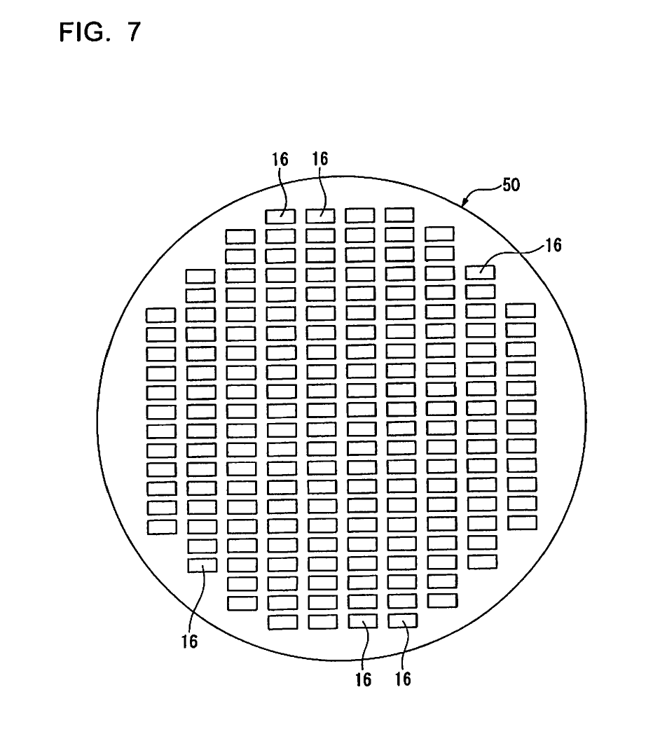

Then, a first wafer fabrication step is performed in which the lid substrate wafer 50 to be the lid substrate 3 is fabricated to make it usable for anodic bonding (S20). First, soda-lime glass is polished to a predetermined thickness, and after washing, a disk-shaped lid substrate wafer 50 is formed from which the work-affected layer on the outermost surface has been removed by etching or the like, as illustrated in FIG. 7 (S21). This is followed by a depression forming step in which a plurality of depressions 16 to provide cavities is formed by etching or the like in the row and column directions on the bonding face of the lid substrate wafer 50 (S22). This completes the first wafer fabrication step.

Concurrently with, or before or after this step, a second wafer fabrication step is performed in which the base substrate wafer 40 to be the base substrate 2 is fabricated to make it usable for anodic bonding (S30). First, soda-lime glass is polished to a predetermined thickness, and after washing, a disk-shaped base substrate wafer 40 is formed from which the work-affected layer on the outermost surface has been removed by etching or the like (S31). This is followed by a through electrodes forming step in which the pairs of through electrodes 13 and 14 are formed in the base substrate wafer 40 (S32).

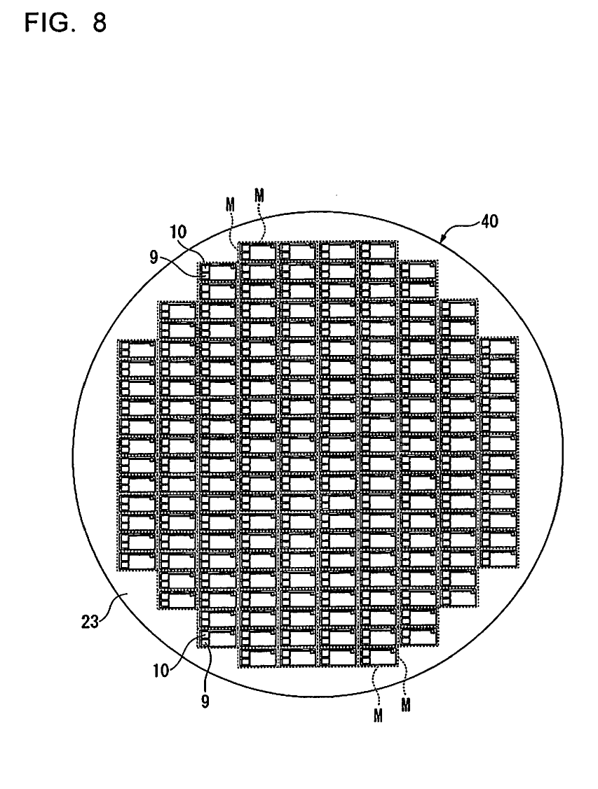

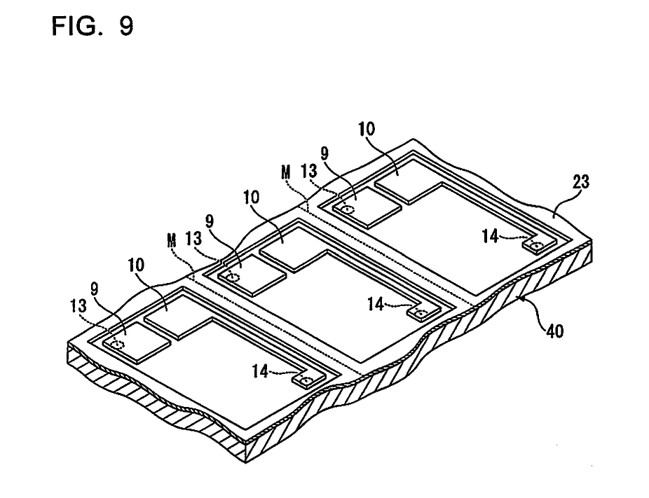

Next, conductive material is patterned on the upper surface of the base substrate wafer 40 to form the bonding film 23 (bonding film forming step; S33) and the inner electrodes 9 and 10 electrically connected to the through electrodes 13 and 14, respectively (inner electrodes forming step; S34), as illustrated in FIGS. 8 and 9. Note that the dotted lines M shown in FIGS. 8 and 9 are cutting lines used in the subsequent cutting step.

The through electrodes 13 and 14 are substantially flush with the upper surface of the base substrate wafer 40, as described above. Accordingly, the inner electrodes 9 and 10 patterned on the upper surface of the base substrate wafer 40 are closely in contact with the through electrodes 13 and 14 without any gap or space. This ensures conductivity between the inner electrode 9 and the through electrode 13, and between the inner electrode 10 and the through electrode 14. This completes the second wafer fabrication step.

In FIG. 6, the inner electrodes forming step (S34) is performed after the bonding film forming step (S33); however, the bonding film forming step (S33) may be performed after the inner electrodes forming step (S34), or these steps may be performed simultaneously. The same effect can be obtained regardless of the order of the steps. Accordingly, the order of these steps may be changed appropriately, as needed.

Then, the piezoelectric vibrating pieces 4 fabricated as above are bonded to the upper surface of the base substrate wafer 40 via their respective inner electrodes 9 and 10 (mount step; S40). First, the bumps 11 and 12 are formed on the inner electrodes 9 and 10, respectively, using gold wires.

In the present embodiment, two bumps of different heights are formed to provide the bumps 11 and 12. Specifically, two bumps 11A and 11B of different heights are formed to provide the bumps 11 along the longitudinal direction of the crystal plate 17. The bump 11A has height H1 substantially the same as the gap between the surface of the base substrate 2 and the surface of the crystal plate 17 to be bump bonded to the bump 11A. The bump 11B has height H2 substantially the same as the gap between the surface of the base substrate 2 and the surface of the crystal plate 17 to be bump bonded to the bump 11B. Similarly, a bump 12A of height H1 and a bump 12B of height H2 are formed to provide the bumps 12. When using gold wires for example, the bumps of different heights can be formed by using wires of different diameters, or by adjusting parameters such as the compression force and compression time of forming the bumps. When using gold wires to form the bumps, the gold wire is bonded to the inner electrodes 9 and 10 using ultrasonic waves and discharge, and then cut at an appropriate timing by further discharge to form a bump of a desired size. For example, when forming two bumps, the bumps 11A (12A) and 11B (12B), that adjoin together at the base, the bump 11A (12A) is formed with a height H1 of 80 to 100 μm, and the bump 11B (12B) with a height H2 of 40 to 70 μm.

Then, with the tapered basal portion of the piezoelectric vibrating piece 4 placed on the bumps 11 and 12, the piezoelectric vibrating piece 4 is pressed against the bumps 11 and 12 while heating the bumps 11 and 12 to a predetermined temperature. In this way, the bumps 11 and 12 provide mechanical support for the piezoelectric vibrating piece 4, and the mount electrodes 7 and 8 and the inner electrodes 9 and 10 are electrically connected to each other, respectively. Further, the bump bonding of the mount electrode 7 of the crystal plate 17 on the bumps 11A and 11B, and the bump bonding of the mount electrode 8 of the crystal plate 17 on the bumps 12A and 12B ensures that the crystal plate 17 is supported parallel to the base substrate 2. As a result, the piezoelectric vibrating piece 4 is supported by being bump bonded and suspended above the base substrate wafer 40. Here, the excitation electrodes 5 and 6 of the piezoelectric vibrating piece 4 conduct to the through electrodes 13 and 14, respectively.

After the piezoelectric vibrating piece 4 is mounted, a mating step is performed in which the lid substrate wafer 50 is mated with the base substrate wafer 40 (S50). Specifically, the wafers 40 and 50 are aligned in position using reference marks or the like (not shown) as a marker. As a result, the piezoelectric vibrating piece 4 mounted as above is housed in the cavity 16 surrounded by the wafers 40 and 50.

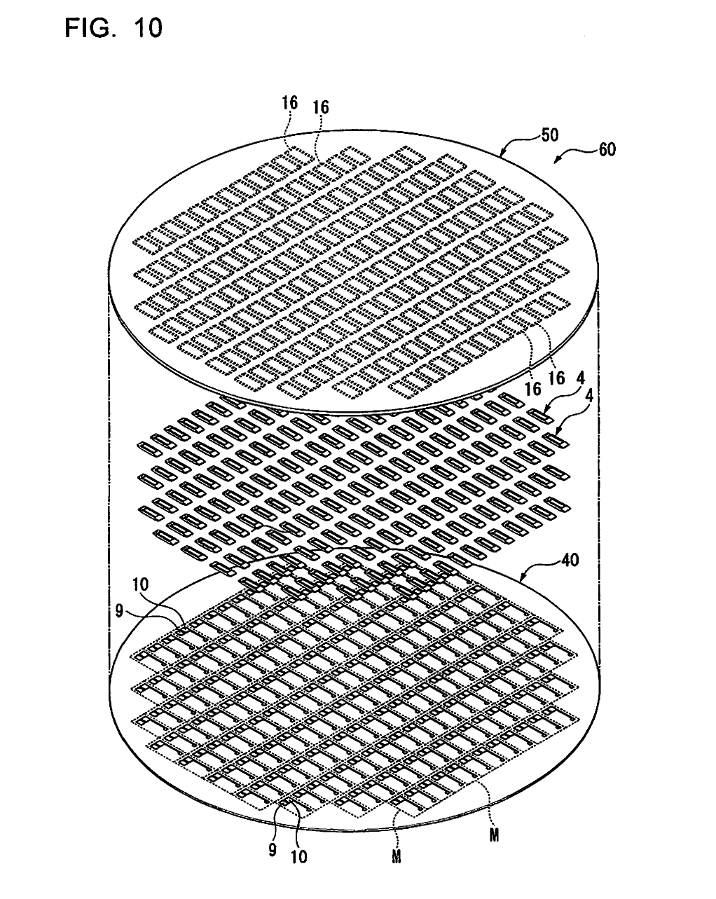

After the mating step, the mated two wafers 40 and 50 are placed in an anodic bonding machine (not shown) to perform a bonding step in which the two wafers are anodically bonded together under application of a predetermined voltage in an atmosphere of a predetermined temperature (S60). Specifically, a predetermined voltage is applied between the bonding film 23 and the lid substrate wafer 50. This causes an electrochemical reaction at the interface between the bonding film 23 and the lid substrate wafer 50, anodically bonding the two with tight adhesion. As a result, the piezoelectric vibrating piece 4 is sealed inside the cavity 16, and a wafer unit 60 in which the base substrate wafer 40 and the lid substrate wafer 50 are bonded together is obtained, as illustrated in FIG. 10. Note that, in FIG. 10, the wafer unit 60 is illustrated in an exploded view, and the bonding film 23 of the base substrate wafer 40 is omitted for ease of illustration. The dotted lines M in FIG. 10 are cutting lines used in the subsequent cutting step.

At the time of anodic bonding, the through holes 24 and 25 formed in the base substrate wafer 40 are completely closed by the through electrodes 13 and 14, and therefore the sealing of the cavity C will not be lost through the through holes 24 and 25.

After anodic bonding, an external electrodes forming step is performed in which conductive material is patterned on the lower surface of the base substrate wafer 40 to form the pairs of external electrodes 21 and 22 electrically connected to the pairs of through electrodes 13 and 14, respectively (S70). The external electrodes 21 and 22 formed in this step can then be used to activate the piezoelectric vibrating piece 4 sealed inside the cavity 16.

As in the case of the inner electrodes 9 and 10, because the through electrodes 13 and 14 are substantially flush with the lower surface of the base substrate wafer 40, the external electrodes 21 and 22 patterned in this step are closely in contact with the through electrodes 13 and 14 without any gap or space. This ensures conductivity between the external electrodes 21 and 22 and the through electrodes 13 and 14.

Next, a cutting step is performed in which the wafer unit 60 bonded as above is cut into smaller pieces along the cutting lines M shown in FIG. 10 (S80). As a result, a plurality of bilayer, surface-mounted piezoelectric vibrators 1 illustrated in FIG. 1 is manufactured at once, each sealing the piezoelectric vibrating piece 4 in the cavity 16 formed between the anodically bonded base substrate 2 and lid substrate 3.

This is followed by an internal electrical characteristics test (S90). Specifically, measurement is made to check properties of the piezoelectric vibrating piece 4, such as resonant frequency, resonant resistance, and drive level characteristics (excitation power dependence of resonant frequency and resonant resistance). Other properties, such as insulation resistance characteristics are also checked. Finally, the piezoelectric vibrator 1 is subjected to an appearance test to check the dimensions, quality, and other conditions of the product. This completes the manufacture of the piezoelectric vibrator 1.

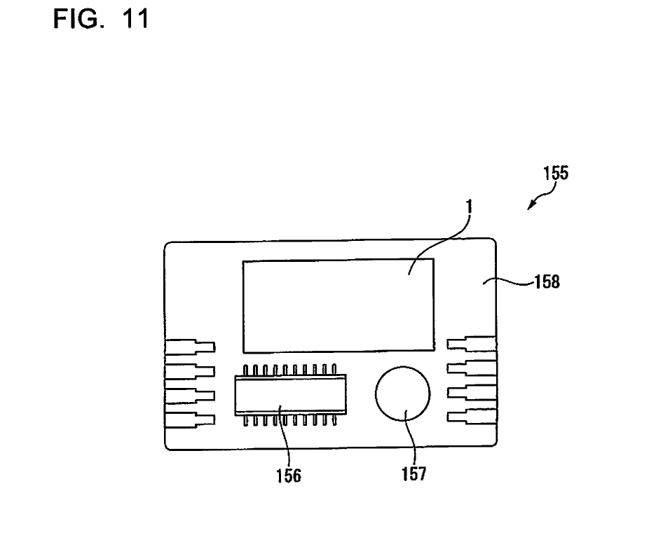

An embodiment of an oscillator including a piezoelectric vibrator according to the present invention is described below with reference to FIG. 11.

As illustrated in FIG. 11, an oscillator 155 is structured to include the piezoelectric vibrator 1 provided as a resonator electrically connected to an integrated circuit 156. The oscillator 155 includes a substrate 158 on which electronic components 157 such as capacitors are mounted. The integrated circuit 156 for the oscillator is mounted on the substrate 158, and the piezoelectric vibrating piece 4 of the piezoelectric vibrator 1 is mounted in the vicinity of the integrated circuit 156. The electronic components 157, the integrated circuit 156, and the piezoelectric vibrator 1 are electrically connected to one another through wiring patterns (not shown). Note that each of these constituting elements is resin molded (not shown).

In the oscillator 155 of this construction, applying a voltage to the piezoelectric vibrator 1 causes the piezoelectric vibrating piece 4 in the piezoelectric vibrator 1 to vibrate. The vibration is transduced into an electrical signal by the piezoelectric characteristics of the piezoelectric vibrating piece 4, and input to the integrated circuit 156. The input electrical signal undergoes various processes in the integrated circuit 156, and output as a frequency signal. In this way, the piezoelectric vibrator 1 serves as a resonator.

Because the oscillator 155 of the present embodiment uses the piezoelectric vibrator 1 having stable electrical characteristics such as frequency characteristics and impedance characteristics, the oscillator 155 has improved quality with stable electrical characteristics.

It should be noted that the present invention is not limited to the embodiment described above, and various modifications of the embodiment that do not depart from the substance of the present invention are intended to be within the scope of the invention. To be more specific, the specific structures and constructions described in the embodiment are merely examples and can be modified appropriately.

For example, the piezoelectric vibrating piece (crystal plate) is not limited to the rectangular plate described in the embodiment, and may be a round plate. The shape of the bumps (bump height) is adjusted according to the shape along the thickness of the piezoelectric vibrating piece (crystal plate).

Further, the crystal plate described in the embodiment as being beveled may be a convex crystal plate.

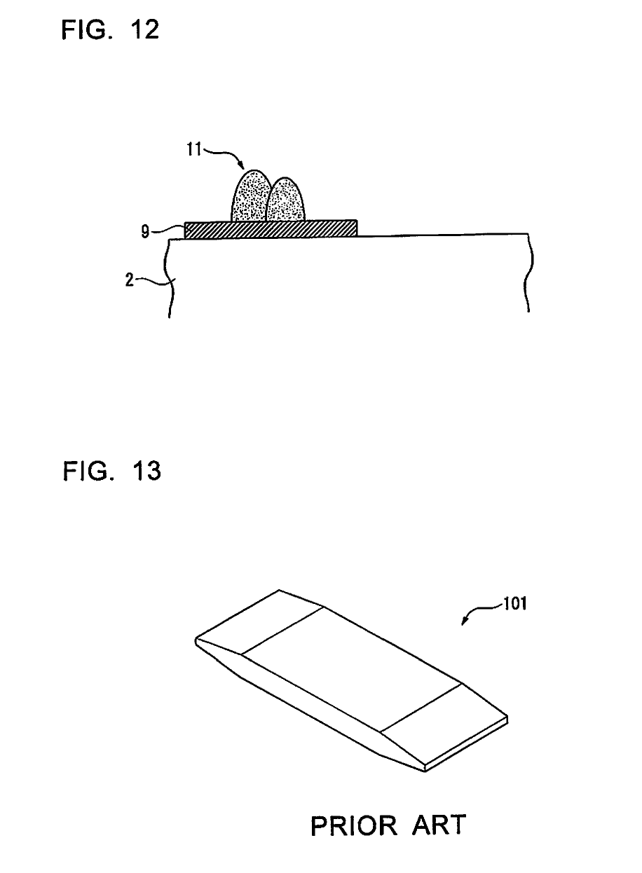

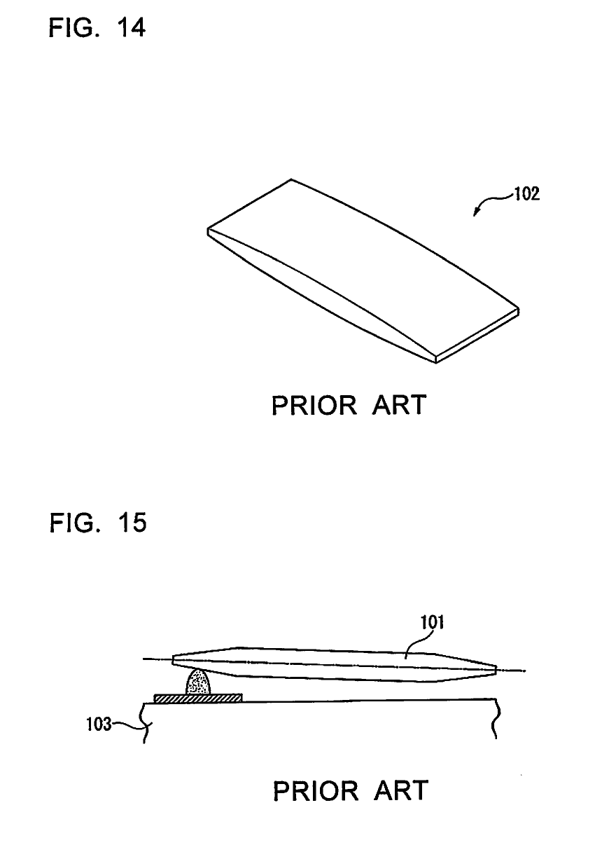

Further, three or more bumps may be provided, though only two bumps are formed along the longitudinal direction of the piezoelectric vibrating piece in this embodiment. The two bumps are spaced apart in this embodiment; however, the bumps may be continuously formed without any gap, as illustrated in FIG. 12.

A plurality of bumps is formed with their apices conforming to the shape of the piezoelectric vibrating piece.

What is claimed is:

1. A piezoelectric vibrator, comprising:
a base substrate;
a lid substrate bonded to the base substrate, and that forms a cavity between the base substrate and the lid substrate;
a piezoelectric vibrating piece housed in the cavity, and that includes a crystal plate having on its outer surface excitation electrodes and mount electrodes electrically connected to the excitation electrodes, and is tapered towards ends along the longitudinal direction;
through electrodes provided in through holes formed through the base substrate;
inner electrodes formed on the base substrate to provide electrical interconnections between the piezoelectric vibrating piece and the through electrodes; and
metal bumps formed on the inner electrodes to provide electrical interconnections between the inner electrodes and the mount electrodes, and to mount the piezoelectric vibrating piece in a cantilever fashion, the metal bumps being provided in a plurality along the longitudinal direction of the piezoelectric vibrating piece, and having heights that become higher towards a position corresponding to an end of the piezoelectric vibrating piece along the longitudinal direction.

2. The piezoelectric vibrator according to claim 1, wherein the piezoelectric vibrating piece is an AT-cut vibrating piece.

3. The piezoelectric vibrator according to claim 1, wherein the metal bumps are gold bumps.

4. The piezoelectric vibrator according to claim 1, wherein the crystal plate has a beveled or convex shape.

5. A method for manufacturing a piezoelectric vibrator which comprises a base substrate; a lid substrate bonded to the base substrate, and that forms a cavity between the base substrate and the lid substrate; a piezoelectric vibrating piece housed in the cavity, and that includes a crystal plate having on its outer surface excitation electrodes and mount electrodes electrically connected to the excitation electrodes, and is tapered towards ends along the longitudinal direction; through electrodes provided in through holes formed through the base substrate; inner electrodes formed on the base substrate to provide electrical interconnections between the piezoelectric vibrating piece and the through electrodes; and metal bumps formed on the inner electrodes to provide electrical interconnections between the inner electrodes and the mount electrodes, and to mount the piezoelectric vibrating piece in a cantilever fashion,
the method comprising:
forming the inner electrodes on the base substrate;
forming the metal bumps on the inner electrodes along the longitudinal direction of the piezoelectric vibrating piece such that the metal bumps have heights that become higher towards a position corresponding to an end of the piezoelectric vibrating piece along the longitudinal direction; and
bonding the mount electrodes of the piezoelectric vibrating piece to the metal bumps to mount the piezoelectric vibrating piece in a cantilever fashion.

6. An oscillator, comprising:
a piezoelectric vibrator of claim 1; and
an integrated circuit electrically connected to the piezoelectric vibrator provided as a resonator.
